(19) United States
(12) Patent Application Publication
(10) Pub. No.: US 2025/0351389 A1
(43) Pub. Date: Nov. 13, 2025

(54) CAPACITOR HAVING IMPROVED QUALITY FACTOR AND/OR REDUCED PLATE RESISTANCE AND METHOD OF IMPLEMENTING THE SAME

(71) Applicant: MACOM TECHNOLOGY SOLUTIONS HOLDINGS, INC., Lowell, MA (US)

(72) Inventor: David Rice, Hollister, CA (US)

(21) Appl. No.: 18/657,441

(22) Filed: May 7, 2024

(51) Int. Cl. H01L 29/94; H01L 23/00

(52) U.S. Cl. CPC H10D 1/66; H01L 24/48; H01L 2224/48195

(57) ABSTRACT

A capacitor component includes at least one dielectric layer, at least one capacitor top metal, and at least one capacitor bottom metal. The at least one capacitor top metal, the at least one capacitor bottom metal, and the at least one dielectric layer being configured as a capacitor. The capacitor component further includes at least one metallic structure configured to improve a quality factor of the capacitor and/or reduce a plate resistance of the capacitor. The at least one metallic structure is arranged on the at least one capacitor top metal.

### BACKGROUND OF THE DISCLOSURE

Capacitors are typically implemented utilizing two conductors having closely spaced surfaces that are insulated from each other by insulation. Additionally, a construction of the two conductors also creates a resistance (a plate resistance), that may increase power dissipated in the capacitor. In this regard, a capacitor quality factor (Q) defined as a ratio of a capacitance reactance Xc and the plate resistance of each conductor. Thus, the quality factor Q of a capacitor and the capacitance C of the capacitor is at least partially a function of construction and arrangement of the two conductors. Accordingly, the capacitance C of the capacitor is generally set during the manufacture of the capacitor. Likewise, the plate resistance is generally set during the manufacture of the capacitor.

In many implementations, it may be beneficial to be able to modify a quality factor Q of a capacitor. In this regard, there are variable capacitors. However, variable capacitors are large, expensive, and/or complex devices.

Accordingly, what is needed is a smaller, less expensive, and/or less complex device and process to modify a quality factor Q of a capacitor. Additionally or alternatively, what is needed is a smaller, less expensive, and/or less complex device and process to reduce a plate resistance of a capacitor.

### SUMMARY OF THE DISCLOSURE

In one aspect, a capacitor component includes at least one dielectric layer. The capacitor component in addition includes at least one capacitor top metal. The capacitor component moreover includes at least one capacitor bottom metal. The capacitor component also includes the at least one capacitor top metal, the at least one capacitor bottom metal, and the at least one dielectric layer being configured as a capacitor. The capacitor component further includes at least one metallic structure configured to improve a quality factor of the capacitor and/or reduce a plate resistance of the capacitor. The capacitor component in addition includes where the at least one metallic structure is arranged on the at least one capacitor top metal.

In one aspect, a capacitor component includes at least one dielectric layer. The capacitor component in addition includes at least one capacitor top metal. The capacitor component moreover includes at least one capacitor bottom metal. The capacitor component also includes the at least one capacitor top metal, the at least one capacitor bottom metal, and the at least one dielectric layer being configured as a capacitor. The capacitor component further includes at least one metallic structure configured to improve a quality factor of the capacitor and/or reduce a plate resistance of the capacitor. The capacitor component in addition includes where the at least one metallic structure comprises at least one wire. The capacitor component moreover includes where the at least one metallic structure is arranged on the at least one capacitor top metal.

In one aspect, a process includes providing at least one dielectric layer. The process in addition includes providing at least one capacitor top metal. The process moreover includes providing at least one capacitor bottom metal. The process also includes configuring the at least one capacitor top metal, the at least one capacitor bottom metal, and the at least one dielectric layer being as a capacitor. The process further includes configuring at least one metallic structure to improve a quality factor of the capacitor and/or reduce a plate resistance of the capacitor. The process in addition includes where the at least one metallic structure comprises at least one wire. The process moreover includes where the at least one metallic structure is arranged on the at least one capacitor top metal.

In one aspect, a process includes providing at least one dielectric layer. The process in addition includes providing at least one capacitor top metal. The process moreover includes providing at least one capacitor bottom metal. The process also includes configuring the at least one capacitor top metal, the at least one capacitor bottom metal, and the at least one dielectric layer being as a capacitor. The process further includes configuring at least one metallic structure to improve a quality factor of the capacitor and/or reduce a plate resistance of the capacitor. The process in addition includes where the at least one metallic structure is arranged on the at least one capacitor top metal.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a cross-sectional end view of a capacitor component according to the disclosure.

FIG. 2 illustrates a top view of a capacitor component according to FIG. 1.

FIG. 3 illustrates another cross-sectional side view of a capacitor component according to FIG. 1.

FIG. 4 illustrates a top view of a capacitor component according to FIG. 1 implemented with an interconnect.

FIG. 5 illustrates a top view of a device implementing multiple implementations of the capacitor component according to FIG. 1 implemented with interconnects.

FIG. 6 illustrates a cross-sectional side view of device implementing the capacitor component according to the disclosure.

FIG. 7 illustrates a perspective view of a package according to the disclosure.

FIG. 8 illustrates a cross-sectional view of the package according to FIG. 7.

FIG. 9 illustrates a perspective view of a package according to the disclosure.

FIG. 10 illustrates a cross-sectional view of the package according to FIG. 9.

FIG. 11 shows a process of making a capacitor component according to the disclosure.

FIG. 12 shows a process of making a package according to the disclosure.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects, as the skilled artisan would recognize, even if not explicitly stated herein. Descriptions of well-known components and processing techniques may be omitted so as not to unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings and in the different embodiments disclosed.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects of the disclosure are directed to a device for implementing a capacitor having improved quality factor. Aspects of the disclosure are further directed to a device for implementing a capacitor having reduced plate resistance. Aspects of the disclosure are directed to a process for implementing a capacitor having improved quality factor. Aspects of the disclosure are further directed to a process for implementing a capacitor having reduced plate resistance.

In aspects, the disclosed device and process may implement a structure on a surface of a capacitor. In aspects, the disclosed device and process may implement a structure on the top surface of a capacitor. In aspects, the disclosed device and process may implement a structure on the top surface of a MOS (Metal-Oxide-Semiconductor) capacitor.

In aspects, the disclosed device and process may implement the structure as a metallic structure, a wire structure, a wire bond structure, a stitched wire bond structure, a looped wire bond structure, a lower height looped wire bond, a zero loop height wire bond, a zero loop height stitched wire bond, and/or the like.

In aspects, the disclosed device and process may reduce DC (direct current) voltage drop across a top metal plate of the capacitor by providing additional cross sectional area (DC). In aspects, the disclosed device and process may reduce DC voltage drop across a top metal plate of the capacitor by providing additional cross sectional area (DC) while simultaneously providing more surface radio frequency (RF) area to the top metal plate of the capacitor. In aspects, the disclosed device and process may address RF power loss across the top metal plate of the MOS capacitor by providing additional cross sectional area (DC).

In aspects, the disclosed device and process may address RF power loss across the top metal plate of the MOS capacitor by providing additional cross sectional area (DC) while simultaneously providing more surface area (RF) to the top metal plate of the capacitor. In aspects, the disclosed device and process may address DC voltage drop as well as RF power loss across a top metal plate of the capacitor by providing additional cross sectional area (DC) while simultaneously providing more surface area (RF) to the top metal plate of the capacitor.

In aspects, the disclosed device and process may enable an adjustment of a capacitor top metal geometry. In aspects, the disclosed device and process may enable an adjustment of a capacitor top metal geometry with respect to a cross sectional area. In aspects, the disclosed device and process may enable an adjustment of a capacitor top metal geometry with respect to a surface area. In aspects, the disclosed device and process may enable an adjustment of a capacitor top metal geometry with respect to a cross sectional area and a surface area.

In aspects, the disclosed device and process may enable an adjustment of a capacitor top metal geometry independently of the capacitor process. In aspects, the disclosed device and process may enable an adjustment of a capacitor top metal geometry independently of an original capacitor manufacturing process. In aspects, the disclosed device and process may enable an adjustment of a MOS capacitor top metal geometry, both in cross sectional area as well as surface area, independently of the MOS capacitor process.

In aspects, the disclosed device and process may be implemented in any thin metal device to reduce both DC and/or RF losses.

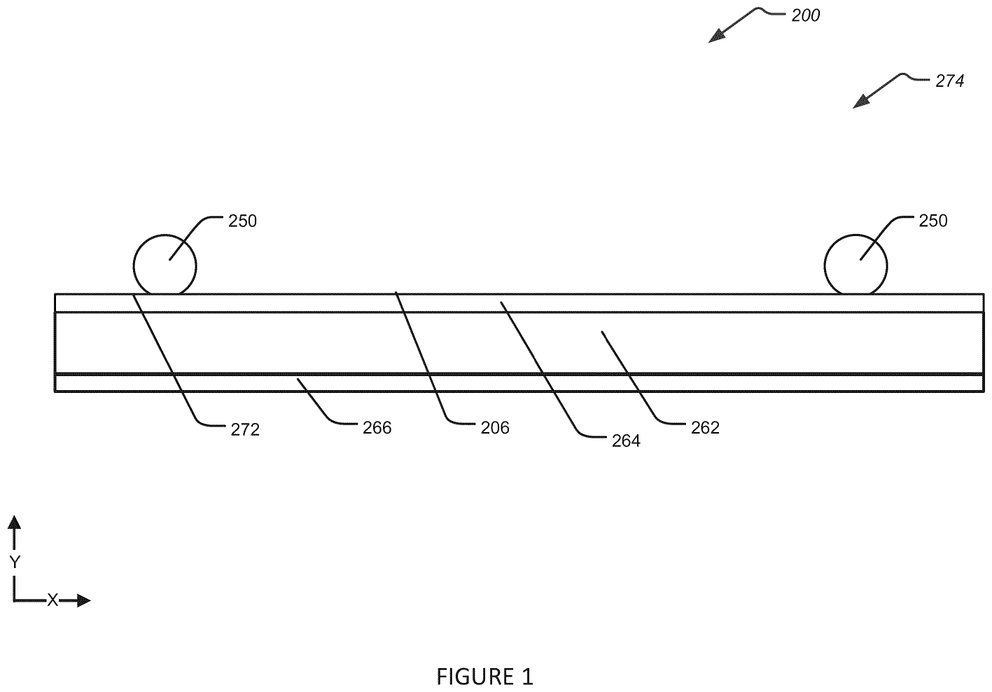

FIG. 1 illustrates a cross-sectional end view of a capacitor component according to the disclosure.

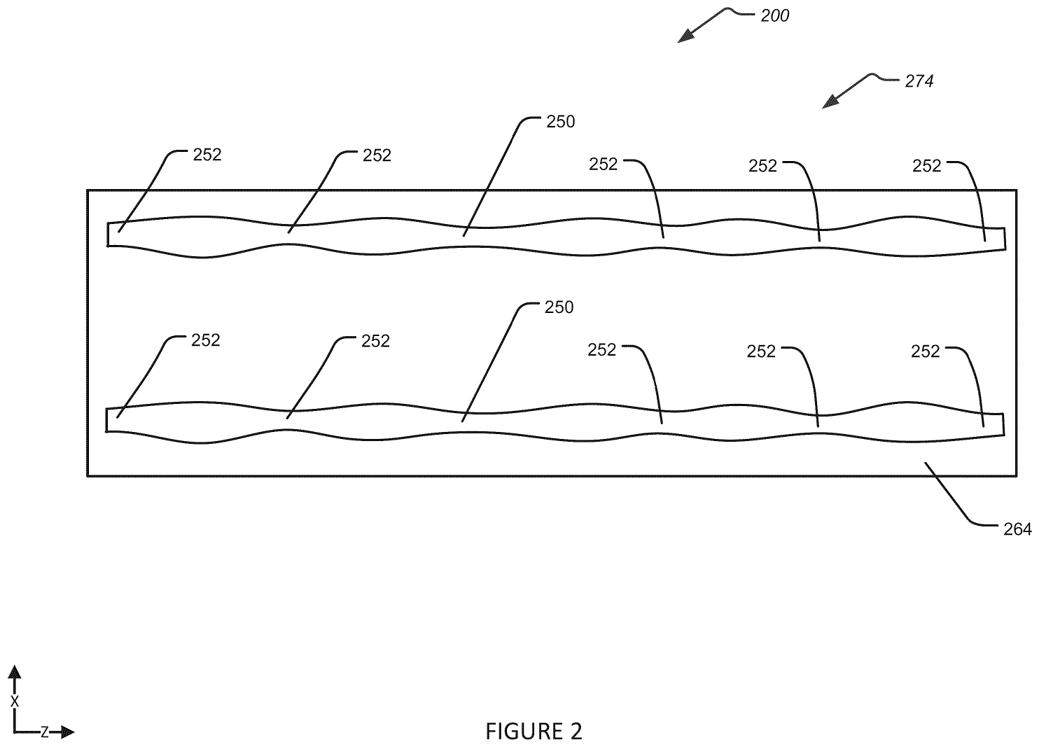

FIG. 2 illustrates a top view of a capacitor component according to FIG. 1.

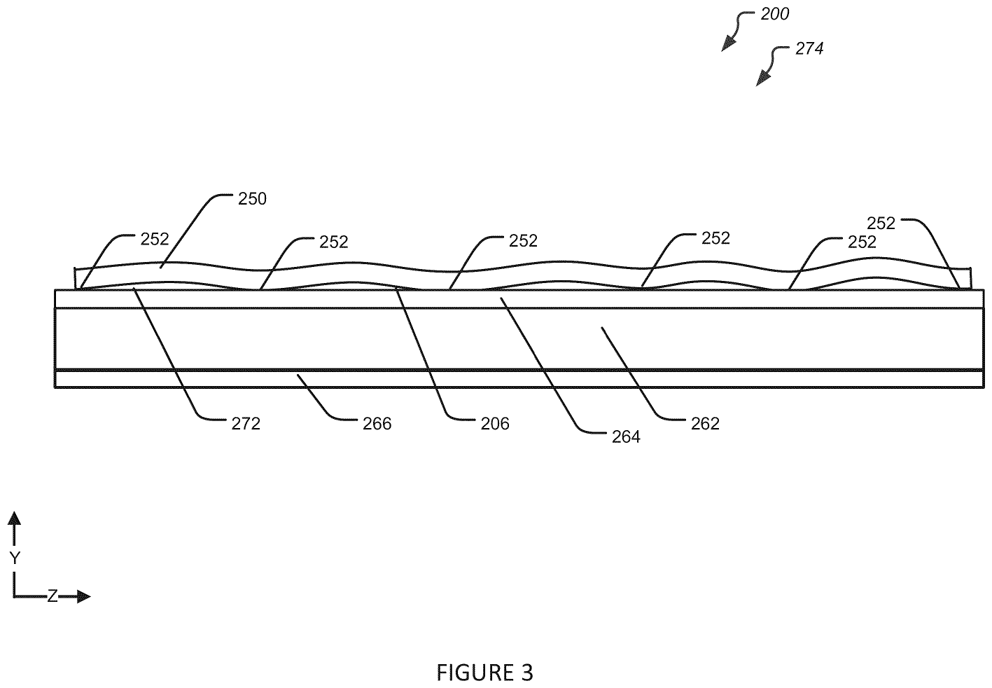

FIG. 3 illustrates another cross-sectional side view of a capacitor component according to FIG. 1.

FIG. 1, FIG. 2, and FIG. 3 may include any one or more other features, components, arrangements, and the like as described herein. In particular, FIG. 1 illustrates a capacitor component 200 that may be configured to have an improved quality factor. In aspects, the capacitor component 200 may be configured to have a reduced plate resistance. In aspects, the capacitor component 200 may be configured to have an improved quality factor and a reduced plate resistance.

The capacitor component 200 may include at least one dielectric layer 262, at least one capacitor top metal 264, at least one capacitor bottom metal 266, and/or the like. In particular, the capacitor component 200 may form a capacitor 274 with the at least one capacitor top metal 264 and the at least one capacitor bottom metal 266 having the at least one dielectric layer 262 therebetween.

Additionally, the capacitor component 200 may include at least one metallic structure 250. In aspects, the at least one metallic structure 250 may be configured as a wire structure, a wire bond structure, a stitched wire bond structure, a looped wire bond structure, a lower height looped wire bond, a zero loop height wire bond, a zero loop height stitched wire bond, and/or the like.

In aspects, the at least one metallic structure 250 may be arranged on the at least one capacitor top metal 264. In aspects, the at least one metallic structure 250 may be arranged directly on the at least one capacitor top metal 264. In aspects, the at least one metallic structure 250 may be connected to the at least one capacitor top metal 264. In aspects, the at least one metallic structure 250 may be directly connected to the at least one capacitor top metal 264. In aspects, the at least one metallic structure 250 may be connected to the at least one capacitor top metal 264 by an adhesive, soldering, sintering, eutectic bonding, thermal compression bonding, ultrasonic bonding/welding, and/or the like as described herein.

In aspects, the at least one metallic structure 250 may be electrically connected to the at least one capacitor top metal 264. In aspects, the at least one metallic structure 250 may be directly electrically connected to the at least one capacitor top metal 264. In aspects, the at least one metallic structure 250 may be electrically connected to the at least one capacitor top metal 264 by an adhesive, soldering, sintering, eutectic bonding, thermal compression bonding, ultrasonic bonding/welding, and/or the like as described herein.

In aspects, the at least one capacitor top metal 264 may include a capacitor upper surface 272. In aspects, the capacitor upper surface 272 may form a connection pad 206 for one or more interconnects 104. In aspects, the at least one metallic structure 250 may be arranged on the capacitor upper surface 272. In aspects, the at least one metallic structure 250 may be arranged directly on the capacitor upper surface 272. In aspects, the at least one metallic structure 250 may be connected to the capacitor upper surface 272. In aspects, the at least one metallic structure 250 may be directly connected to the capacitor upper surface 272. In aspects, the at least one metallic structure 250 may be connected to the capacitor upper surface 272 by an adhesive, soldering, sintering, eutectic bonding, thermal compression bonding, ultrasonic bonding/welding, and/or the like as described herein.

In aspects, the at least one metallic structure 250 may be electrically connected to the capacitor upper surface 272. In aspects, the at least one metallic structure 250 may be directly electrically connected to the capacitor upper surface 272. In aspects, the at least one metallic structure 250 may be electrically connected to the capacitor upper surface 272 by an adhesive, soldering, sintering, eutectic bonding, thermal compression bonding, ultrasonic bonding/welding, and/or the like as described herein.

In aspects, there may be two, three, four, five, six, seven, eight, nine, ten, or more implementations of the at least one metallic structure 250. As illustrated in FIG. 1, the capacitor component 200 is shown having two implementations of the at least one metallic structure 250.

In aspects, the at least one metallic structure 250 may be formed of one or more of Aluminum, Copper, Silver, Gold, like materials, combinations thereof, and/or the like. In aspects, the at least one metallic structure 250 may be implemented by one or more of ball bonding, wedge bonding, compliant bonding, and/or the like. In aspects, forming the at least one metallic structure 250 may include using one or more of ball bonding, wedge bonding, compliant bonding, and/or the like. In aspects, forming the at least one metallic structure 250 may include utilization of heat. In aspects, forming the at least one metallic structure 250 may include one or more of downward pressure, ultrasonic energy, heat, and/or the like to attach the at least one metallic structure 250 to the at least one capacitor top metal 264. In aspects, forming the at least one metallic structure 250 may include implementing a wire bonding machine.

In aspects, the at least one metallic structure 250 may be configured to modify the capacitor 274 to have an improved quality factor. In aspects, the at least one metallic structure 250 may be configured to modify the capacitor 274 to have a reduced plate resistance. In aspects, the at least one metallic structure 250 may be configured to modify the capacitor 274 to have an improved quality factor and a reduced plate resistance.

In aspects, the at least one metallic structure 250 may be configured to modify the capacitor 274 to have an improved quality factor through implementation of an additional metallic mass provided by the at least one metallic structure 250. In aspects, the at least one metallic structure 250 may be configured to modify the capacitor 274 to have a reduced plate resistance through implementation of an additional metallic mass provided by the at least one metallic structure 250. In aspects, the at least one metallic structure 250 may reduce an Equivalent Series Resistance (ESR) of the capacitor 274. In aspects, the at least one metallic structure 250 may reduce an Equivalent Series Resistance (ESR) of the capacitor 274 by more than 10 milliohms, 50 milliohms, 100 milliohms, 200 milliohms, 300 milliohms, 400 milliohms, 500 milliohms, or 600 milliohms. In aspects, the at least one metallic structure 250 may reduce an Equivalent Series Resistance (ESR) of the capacitor 274 by more than 10 milliohms-600 milliohms, 10 milliohms-50 milliohms, 10 milliohms-100 milliohms, 10 milliohms-200 milliohms, 10 milliohms-300 milliohms, 10 milliohms-400 milliohms, 10 milliohms-500 milliohms, or other ranges between 10 milliohms-600 milliohms.

In aspects and with reference to FIG. 2 in FIG. 3, the at least one metallic structure 250 may be configured as a wire structure. Further, the at least one metallic structure 250 may be configured as a stitched wire bond structure having bond configurations 252. In aspects, the bond configurations 252 may bond the at least one metallic structure 250 to the at least one capacitor top metal 264 and/or the capacitor upper surface 272.

In aspects, the at least one metallic structure 250 may include the bond configurations 252 at terminal ends thereof. In particular, the at least one metallic structure 250 may include the bond configurations 252 at terminal ends thereof adjacent edges of the capacitor component 200. Additionally, the at least one metallic structure 250 may include additional implementations of the bond configurations 252 between the terminal ends thereof. In aspects, there may be two, three, four, five, six, seven, eight, nine, ten, or more implementations of the bond configurations 252 for each implementation of the at least one metallic structure 250.

In aspects, the at least one metallic structure 250 may be a looped wire bond structure such that portions of the at least one metallic structure 250 may extend vertically above the at least one capacitor top metal 264. In particular, the at least one metallic structure 250 may be a looped wire bond structure such that portions of the at least one metallic structure 250 may extend vertically above the at least one capacitor top metal 264 with loop portions arranged between the bond configurations 252. In aspects, the at least one metallic structure 250 may be a zero loop height stitched wire bond such that the loops of the at least one metallic structure 250 between the bond configurations 252 remaining contact with the at least one capacitor top metal 264, extend a slight distance above the at least one capacitor top metal 264, and/or the like. In other aspects, the at least one metallic structure 250 may include other types of loops.

In aspects, the at least one metallic structure 250 may be implemented as a structure on a surface of the capacitor 274. In aspects, the at least one metallic structure 250 may implement a structure on the top surface of the capacitor 274. In aspects, the capacitor 274 may be a MOS (Metal-Oxide-Semiconductor) capacitor.

In aspects, the at least one metallic structure 250 may implement the structure as a metallic structure, a wire structure, a wire bond structure, a stitched wire bond structure, a looped wire bond structure, a lower height looped wire bond, a zero loop height wire bond, a zero loop height stitched wire bond, and/or the like.

In aspects, the at least one metallic structure 250 may reduce DC (direct current) voltage drop across a top metal plate of the capacitor 274 by providing additional cross sectional area (DC). In aspects, the at least one metallic structure 250 may reduce DC voltage drop across a top metal plate of the capacitor 274 by providing additional cross sectional area (DC) while simultaneously providing more surface radio frequency (RF) area to the top metal plate of the capacitor 274. In aspects, the at least one metallic structure 250 may address RF power loss across the top metal plate of the capacitor 274 by providing additional cross sectional area (DC).

In aspects, the at least one metallic structure 250 may address RF power loss across the top metal plate of the capacitor 274 by providing additional cross sectional area (DC) while simultaneously providing more surface area (RF) to the top metal plate of the capacitor. In aspects, the at least one metallic structure 250 may address DC voltage drop as well as RF power loss across a top metal plate of the capacitor 274 by providing additional cross sectional area (DC) while simultaneously providing more surface area (RF) to the top metal plate of the capacitor 274.

In aspects, the at least one metallic structure 250 may enable an adjustment of a top metal geometry of the capacitor 274. In aspects, the at least one metallic structure 250 may enable an adjustment of a top metal geometry of the capacitor 274 with respect to a cross sectional area. In aspects, the at least one metallic structure 250 may enable an adjustment of a top metal geometry of the capacitor 274 with respect to a surface area. In aspects, the at least one metallic structure 250 may enable an adjustment of a top metal geometry of the capacitor 274 with respect to a cross sectional area and a surface area.

In aspects, the at least one metallic structure 250 may enable an adjustment of a top metal geometry of the capacitor 274 independently of the capacitor process. In aspects, the at least one metallic structure 250 may enable an adjustment of a top metal geometry of the capacitor 274 independently of an original capacitor manufacturing process. In aspects, the at least one metallic structure 250 may enable an adjustment of a MOS capacitor top metal geometry, both in cross sectional area as well as surface area, independently of the MOS capacitor process. In aspects, the at least one metallic structure 250 may enable implementation of any thin metal device to reduce both DC and/or RF losses.

The at least one capacitor top metal 264 and/or the at least one capacitor bottom metal 266 may be arranged parallel to the x-axis as illustrated, the at least one capacitor top metal 264 may be continuous and arranged parallel the at least one capacitor bottom metal 266. Moreover, the at least one capacitor top metal 264 may be arranged vertically above the at least one capacitor bottom metal 266 along the y-axis as illustrated.

In some aspects, a side edge of the at least one capacitor top metal 264 along the x-axis as illustrated may be generally or substantially aligned with an edge of the at least one capacitor bottom metal 266. In some aspects, a first side edge of the at least one capacitor top metal 264 along the x-axis as illustrated may be aligned with a first side edge of the at least one capacitor bottom metal 266 and a second side edge of the at least one capacitor top metal 264 along the x-axis as illustrated may be aligned with a second side edge of the at least one capacitor bottom metal 266.

The at least one capacitor bottom metal 266 and/or the at least one capacitor top metal 264 may comprise a metallic material such as copper, gold, nickel, palladium, silver, tin, a gold tin alloy, and the like, and combinations thereof. In one aspect, the at least one capacitor bottom metal 266 may have a thickness along the y-axis of 0.1 microns to 0.6 microns, 0.1 microns to 0.2 microns, 0.2 microns to 0.3 microns, 0.3 microns to 0.4 microns, 0.4 microns to 0.5 microns, or 0.5 microns to 0.6 microns.

The at least one dielectric layer 262 may be arranged on the at least one capacitor bottom metal 266. In particular, there may be one or more intervening layers or structures between the at least one dielectric layer 262 and the at least one capacitor bottom metal 266 (not shown). In other aspects, the at least one dielectric layer 262 may be directly arranged on the at least one capacitor bottom metal 266. In one aspect, the at least one dielectric layer 262 may be continuous. The at least one dielectric layer 262 may include SiN, AlO, SiO, SiO₂, AlN, or the like or combinations thereof together with other intervening layers. The at least one dielectric layer 262 may have any thickness along a y-axis to provide the desired capacitance density, capacitance, standoff voltage, and/or the like. In some aspects, the at least one dielectric layer 262 may have a thickness along the y-axis of 100 Å to 11000 Å, 100 Å to 1000 Å, 1000 Å to 2000 Å, 2000 Å to 3000 Å, 3000 Å to 4000 Å, 4000 Å to 5000 Å, 5000 Å to 6000 Å, 6000 Å to 7000 Å, 7000 Å to 8000 Å, 8000 Å to 9000 Å, 9000 Å to 10000 Å, or 10000 Å to 11000 Å. In some aspects, the at least one dielectric layer 262 may have a thickness along the y-axis of greater than 10000 Å.

The at least one capacitor top metal 264 may be arranged on the at least one dielectric layer 262. In particular, there may be one or more intervening layers or structures between the at least one capacitor top metal 264 and the at least one dielectric layer 262 (not shown). In other aspects, the at least one capacitor top metal 264 may be directly arranged on the at least one dielectric layer 262. The at least one capacitor top metal 264 may be formed as a metal surface on an upper surface the at least one dielectric layer 262 and may comprise a metallic material such as copper, gold, nickel, palladium, silver, tin, a gold tin alloy, and the like, and combinations thereof. In some aspects, the at least one capacitor top metal 264 may comprise stacked layers. In one aspect, the at least one capacitor top metal 264 may have a thickness along the y-axis of 0.1 microns to 7 microns, 0.1 microns to 0.2 microns, 0.2 microns to 0.3 microns, 0.3 microns to 0.4 microns, 0.4 microns to 0.5 microns,0.5 microns to 0.6 microns, 0.6 microns to 0.7 microns, 0.7 microns to 1 microns, 1 microns to 2 microns, 2 microns to 3 microns, 3 microns to 4 microns, 4 microns to 5 microns, 5 microns to 6 microns, or 6 microns to 7 microns.

In aspects, one or more of the at least one capacitor bottom metal 266, the at least one capacitor top metal 264, and/or the connection pad 206 may be located in a plane generally parallel to the x-axis as illustrated. In this regard, generally may be defined to be within 0°-15°, 0°-2°, 2°-4°, 4°-6°, 6°-8°, 8°-10°, 10°-12°, or 12°-15°.

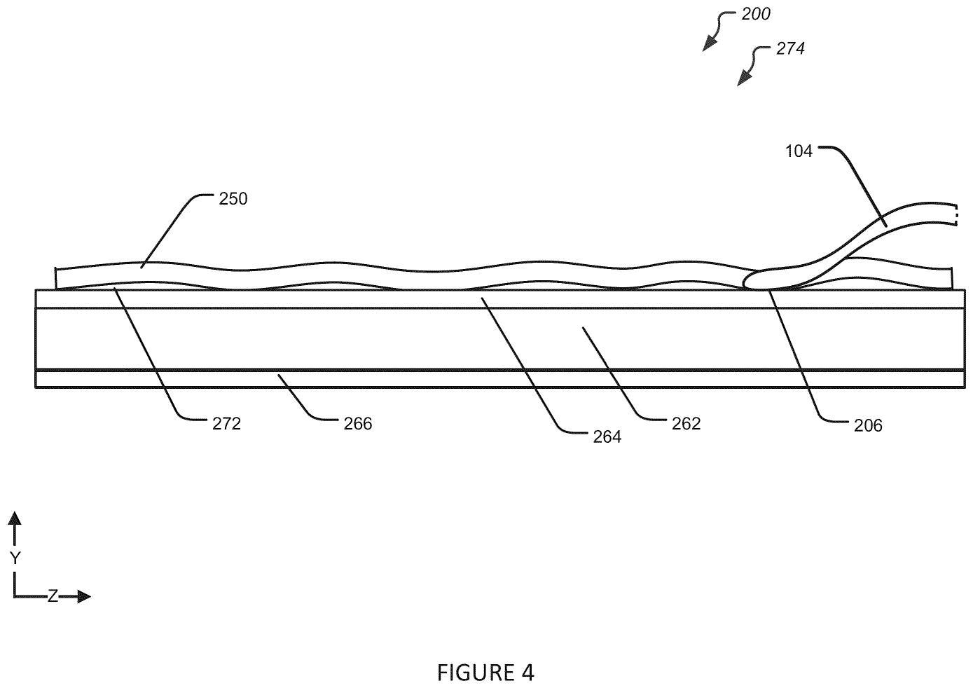

FIG. 4 illustrates a top view of a capacitor component according to FIG. 1 implemented with an interconnect.

In particular, FIG. 4 illustrates a top view of a capacitor component according to FIG. 1 implemented with the one or more interconnects 104. In this regard, FIG. 4 illustrates that the capacitor component 200 may be connected to another device or component with the one or more interconnects 104. In particular, the one or more interconnects 104 may connect to the at least one capacitor top metal 264 and/or the capacitor upper surface 272. In aspects, the one or more interconnects 104 may connect to the at least one capacitor top metal 264 and/or the capacitor upper surface 272 by an adhesive, soldering, sintering, eutectic bonding, thermal compression bonding, ultrasonic bonding/welding, and/or the like as described herein.

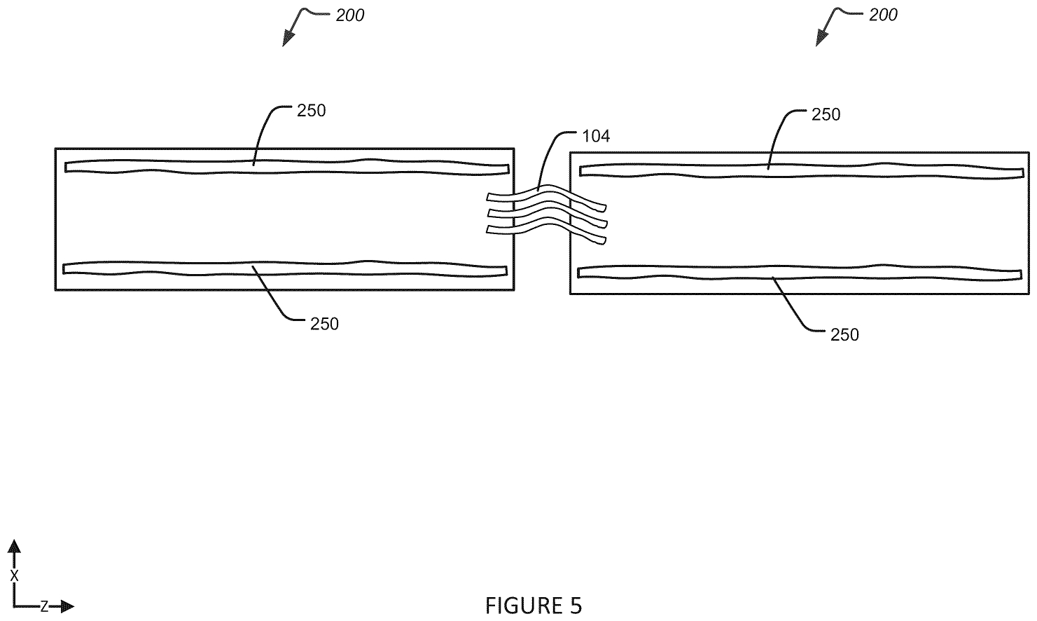

FIG. 5 illustrates a top view of a device implementing multiple implementations of the capacitor component according to FIG. 1 implemented with interconnects.

In particular, a device 100 may have multiple implementations of the capacitor component 200. In aspects, the multiple implementations of the capacitor component 200 may be connected by the one or more interconnects 104. In aspects of the device 100, the multiple implementations of the capacitor component 200 may also be connected to other components of the device 100. In other aspects of the device 100, the multiple implementations of the capacitor component 200 may be connected to other components of the device 100.

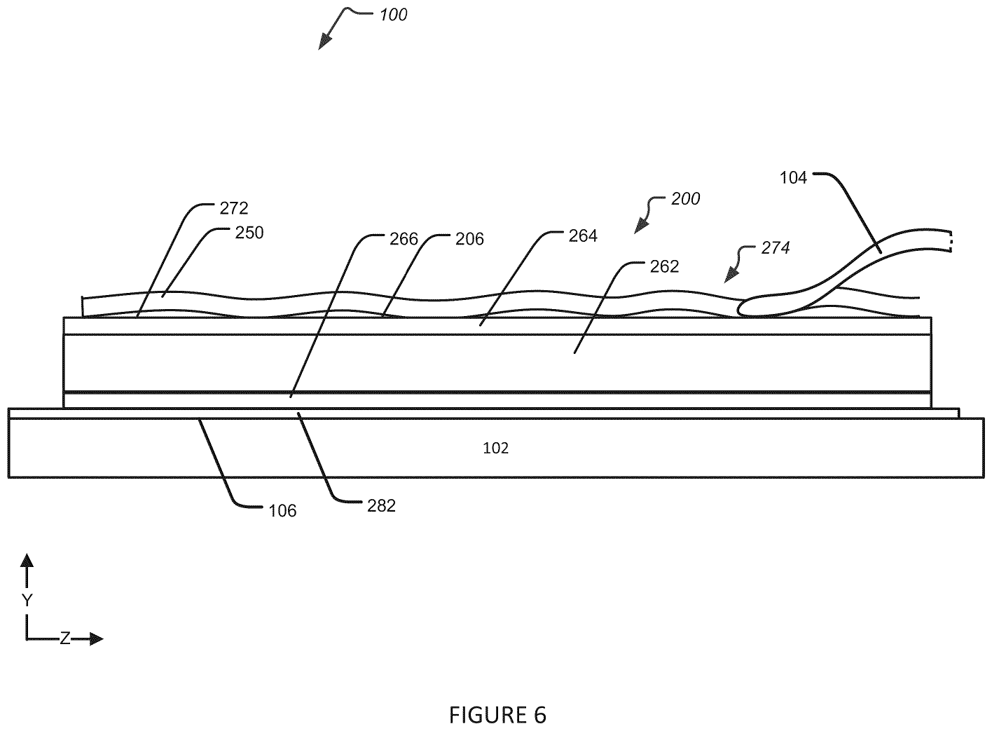

FIG. 6 illustrates a cross-sectional side view of device implementing the capacitor component according to the disclosure.

In particular, FIG. 6 illustrates a device 100 that may implement the capacitor component 200. In aspects, the device 100 may include a plurality of the capacitor component 200; in aspects the device 100 may include a single implementation of the capacitor component 200; and in aspects the device 100 may include a plurality of implementations of the capacitor component 200.

The device 100 may include a support component 102. The support component 102 may be a printed circuit board, a Monolithic Microwave Integrated Circuit (MMIC), a support, and/or the like. The device 100 may further include one or more interconnects 104 that may connect to the connection pad 206. The one or more interconnects 104 may be implemented as one or more wires, wire bonds, leads, clips, and/or the like. In the aspect illustrated in FIG. 6, the support component 102 of the device 100 implements a single implementation of the one or more connections 282. The one or more connections 282 may be a pillar, a bump, pad, a surface, a trace, solder bumping, a Cu bump, a Cu pillar, and/or the like on a surface 106 of the support component 102.

The one or more interconnects 104 may be include various metal materials including one or more of aluminum, copper, silver, gold, and/or the like. The one or more interconnects 104 may connect to the connection pad 206 by an adhesive, soldering, sintering, eutectic bonding, thermal compression bonding, ultrasonic bonding/welding, a clip component, and/or the like as described herein.

The support component 102 may be implemented as a printed circuit board. The printed circuit board implementation of the support component 102 may include the one or more connections 282 arranged on an upper surface of the printed circuit board implementation of the support component 102. The one or more connections 282 may connect the printed circuit board implementation of the support component 102 to the capacitor component 200. In particular, the one or more connections 282 may connect the printed circuit board implementation of the support component 102 to the at least one capacitor bottom metal 266 of the capacitor component 200. The one or more connections 282 may connect by an adhesive, soldering, sintering, eutectic bonding, thermal compression bonding, ultrasonic bonding/welding, a clip component, and/or the like as described herein.

The support component 102 may be implemented as a MMIC. The MMIC implementation of the support component 102 may include one or more connections 282 arranged on an upper surface of the MMIC implementation of the support component 102. The one or more connections 282 may connect the MMIC of the support component 102 to the capacitor component 200. In particular, the one or more connections 282 may connect the MMIC implementation of the support component 102 to the capacitor component 200. The one or more connections 282 may connect by an adhesive, soldering, sintering, eutectic bonding, thermal compression bonding, ultrasonic bonding/welding, a clip component, and/or the like as described herein. In particular, the MMIC implementation of the support component 102 may be implemented utilizing numerous types of device technology, device topology, semiconductor types, transistor types, with one or more active areas, and the like.

The support component 102 may be implemented as a metal submount and may be implemented as a support, a surface, a package support, a package surface, a package support surface, a flange, a metal flange, a heat sink, a common source support, a common source surface, a common source package support, a common source package surface, a common source package support surface, a common source flange, a common source heat sink, a leadframe, a metal leadframe and/or the like. The support component 102 may include an insulating material, a dielectric material, and/or the like. The one or more connections 282 may connect the metal submount of the support component 102 to the capacitor component 200. In particular, the one or more connections 282 may connect the metal submount implementation of the support component 102 to the at least one capacitor bottom metal 266 of the capacitor component 200. The one or more connections 282 may connect by an adhesive, soldering, sintering, eutectic bonding, thermal compression bonding, ultrasonic bonding/welding, a clip component, and/or the like as described herein.

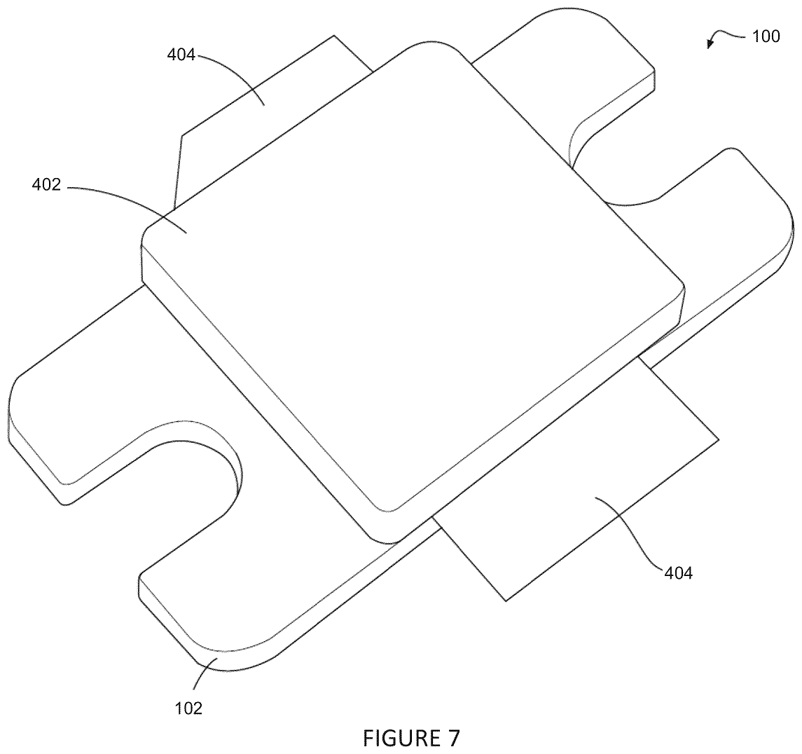

FIG. 7 illustrates a perspective view of a package according to the disclosure.

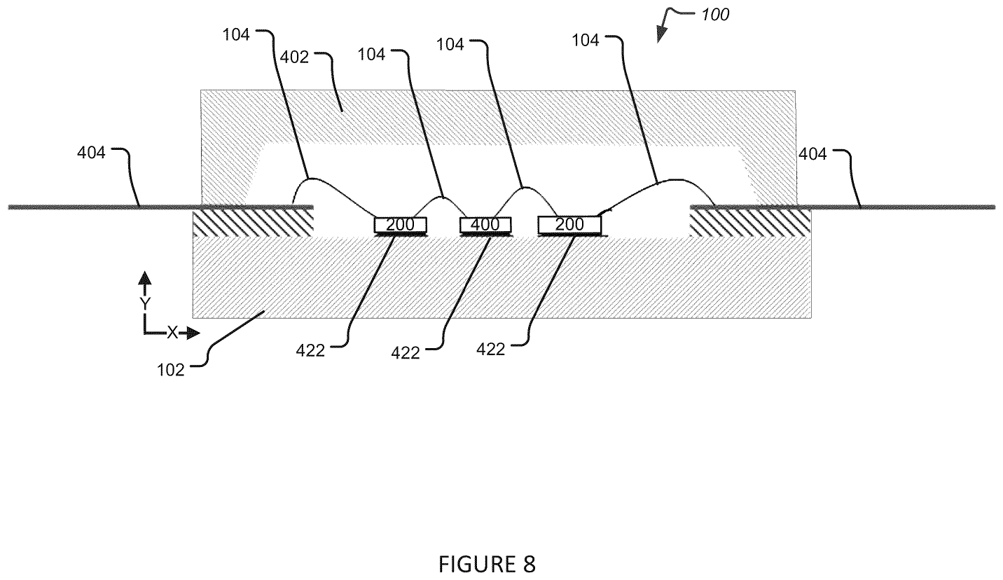

FIG. 8 illustrates a cross-sectional view of the package according to FIG. 7.

FIG. 7 and FIG. 8 may include any one or more other features, components, arrangements, and the like as described herein. In particular, FIG. 7 and FIG. 8 illustrate that the device 100 may be implemented as a RF package, a RF amplifier package, a RF power amplifier package, a RF power transistor package, a RF power amplifier transistor package, and/or the like as described herein. The device 100 may include one or more semiconductor devices 400 and the capacitor component 200.

The one or more semiconductor devices 400 may include a wide band-gap semiconductor device, an ultra-wideband device, a GaN based device, a Metal Semiconductor Field-Effect Transistor (MESFET), a Metal Oxide Field Effect Transistor (MOSFET), a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, a power module, a gate driver, a component such as a General-Purpose Broadband component, a Telecom component, a L-Band component, a S-Band component, a X-Band component, a C-Band component, a Ku-Band component, a Satellite Communications component, a Doherty configuration and/or the like.

The device 100 may be implemented to include an open cavity configuration suitable for use with the capacitor component 200 of the disclosure. In particular, the open cavity configuration may utilize an open cavity package design. In some aspects, the open cavity configuration may include a lid or other enclosure for protecting interconnects, circuit components, the capacitor component 200, the one or more semiconductor devices 400, and/or the like. The device 100 may include a ceramic body 402 and one or more metal contacts 404. In other aspects, the device 100 may include a plurality of the one or more metal contacts 404; and in aspects the device 100 may include a plurality of parallel implementations of the one or more metal contacts 404 and parallel implementations of the one or more semiconductor devices 400.

Inside the device 100, the one or more semiconductor devices 400 may be attached to the support component 102 via a die attach material 422. One or more interconnects 104 may couple the one or more semiconductor devices 400 to a first one of the one or more metal contacts 404, a second one of the one or more metal contacts 404, the capacitor component 200, and/or the like. Additionally, inside the device 100, the capacitor component 200 may be arranged on the support component 102 via a die attach material 422 with the one or more interconnects 104 shown in an exemplary configuration that may connect between the device 100, the capacitor component 200, and/or the one or more semiconductor devices 400. The support component 102 may dissipate the heat generated by the one or more semiconductor devices 400 and the capacitor component 200, while simultaneously isolating and protecting the one or more semiconductor devices 400 and the capacitor component 200 from the outside environment.

Additionally, the one or more semiconductor devices 400 may include one or more transistor dies that may include one or more laterally-diffused metal-oxide semiconductor (LDMOS) transistors, GaN based transistors, Metal Semiconductor Field-Effect transistors (MESFET), Metal Oxide Field Effect Transistors (MOSFET), Junction Field Effect Transistors (JFET), Bipolar Junction Transistors (BJT), Insulated Gate Bipolar Transistors (IGBT), high-electron-mobility transistors (HEMT), Wide Band Gap (WBG) transistors, and/or the like.

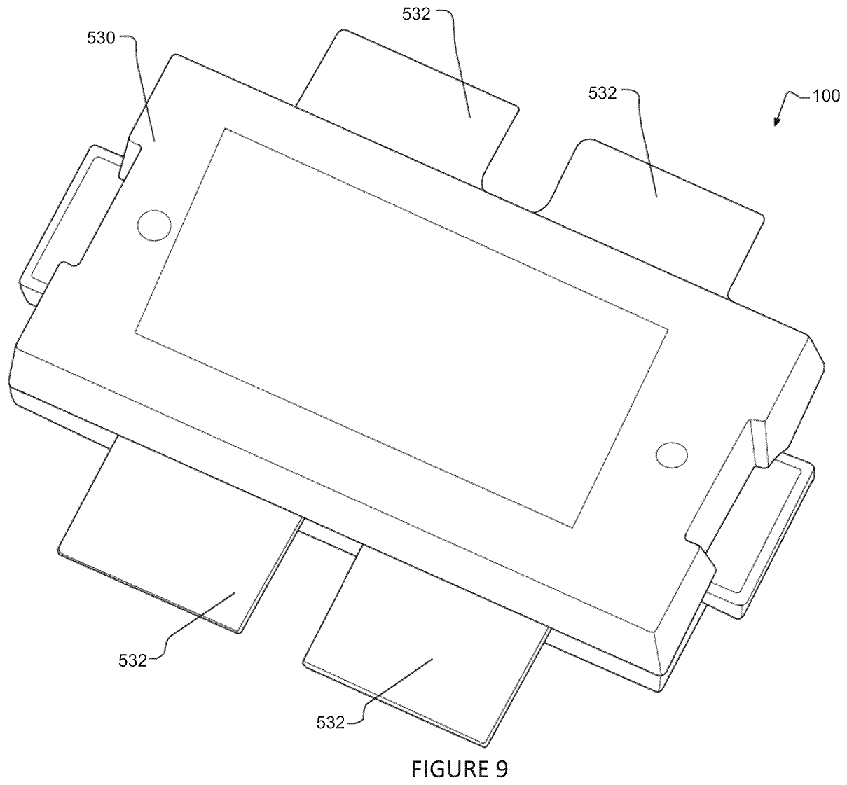

FIG. 9 illustrates a perspective view of a package according to the disclosure.

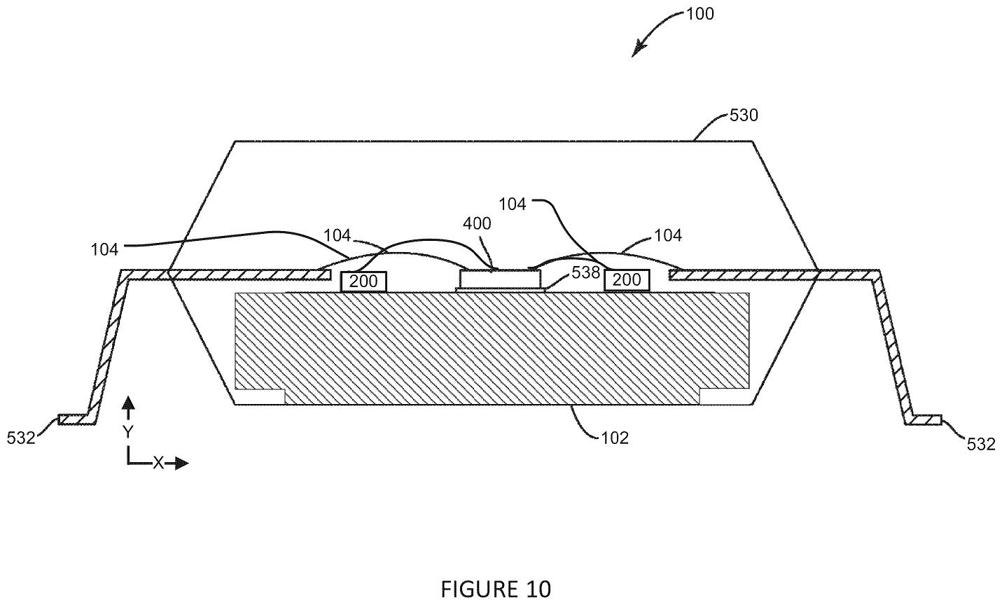

FIG. 10 illustrates a cross-sectional view of the package according to FIG. 9.

FIG. 9 and FIG. 10 may include any one or more other features, components, arrangements, and the like as described herein. In particular, FIG. 9 and FIG. 10 show another exemplary implementation of the device 100 that may include any one or more other features, components, arrangements, and the like as described herein. In particular, FIG. 9 and FIG. 10 show the device 100 may be implemented as a RF package, a RF amplifier package, a RF power amplifier package, a RF power transistor package, a RF power amplifier transistor package, and/or the like as described herein. The device 100 may include the one or more semiconductor devices 400, the capacitor component 200, and/or the like.

Additionally, inside the device 100, the capacitor component 200 may be arranged on the support component 102 as described herein with the one or more interconnects 104 shown in an exemplary configuration. The device 100 may include an over-mold 530, one or more input/output pins 532, and the support component 102. The over-mold 530 may substantially surround the one or more semiconductor devices 400, which are mounted on the support component 102 using a die attach material 538. The over-mold 530 may be formed of a plastic or a plastic polymer compound, which may be injection molded around the support component 102, the one or more semiconductor devices 400, the capacitor component 200, and/or the like, thereby providing protection from the outside environment. The one or more semiconductor devices 400 and/or the capacitor component 200 may be coupled to the one or more input/output pins 532 via the one or more interconnects 104.

In one aspect, the over-mold configuration may substantially surround the one or more semiconductor devices 400, the capacitor component 200, and/or the like. The over-mold configuration may be formed of a plastic, a mold compound, a plastic compound, a polymer, a polymer compound, a plastic polymer compound, and/or the like. The over-mold configuration may be injection molded, transfer molded, and/or compression molded around the one or more semiconductor devices 400, the capacitor component 200, and/or the like, thereby providing protection for the capacitor component 200, the one or more semiconductor devices 400, and other components of the device 100 from the outside environment.

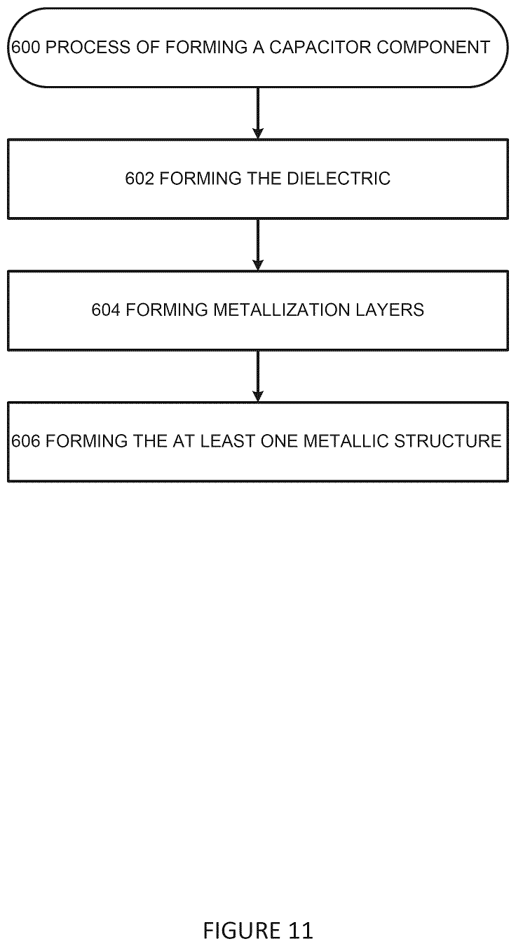

FIG. 11 shows a process of making a capacitor component according to the disclosure.

FIG. 11 may include any one or more other features, components, arrangements, and the like as described herein. In particular, FIG. 11 illustrates a process of forming a capacitor component 600 that relates to the capacitor component 200 as described herein. It should be noted that the aspects of the process of forming a capacitor component 600 may be performed in a different order consistent with the aspects described herein. Additionally, it should be noted that portions of the process of forming a capacitor component 600 may be performed in a different order consistent with the aspects described herein. Moreover, the process of forming a capacitor component 600 may be modified to have more or fewer processes consistent with the various aspects disclosed herein.

The process of forming a capacitor component 600 may include forming the dielectric 602. In particular, the forming the dielectric 602 may include forming the at least one dielectric layer 262 of the capacitor component 200 and/or the capacitor 274 as described herein.

Further, the process of forming a capacitor component 600 may include forming metallization layers 604. In particular, the forming metallization layers 604 may include forming the at least one capacitor top metal 264 and/or the at least one capacitor bottom metal 266 of the capacitor component 200 and/or the capacitor 274 as described herein.

Additionally, the process of forming a capacitor component 600 may include forming the at least one metallic structure 606. In particular, the forming the at least one metallic structure 606 may include forming the at least one metallic structure 250 of the capacitor component 200 and/or the capacitor 274 as described herein.

In aspects, the at least one metallic structure 250 may be formed of one or more of Aluminum, Copper, Silver, Gold, like materials, combinations thereof, and/or the like. In aspects, the at least one metallic structure 250 may be implemented by one or more of ball bonding, wedge bonding, compliant bonding, and/or the like. In aspects, the forming the at least one metallic structure 606 may include one or more of ball bonding, wedge bonding, compliant bonding, and/or the like. In aspects, the forming the at least one metallic structure 606 may include utilization of heat. In aspects, the forming the at least one metallic structure 606 may include one or more of downward pressure, ultrasonic energy, heat, and/or the like to attach the at least one metallic structure 250 to the at least one capacitor top metal 264. In aspects, the forming the at least one metallic structure 606 may include implementing a wire bonding machine.

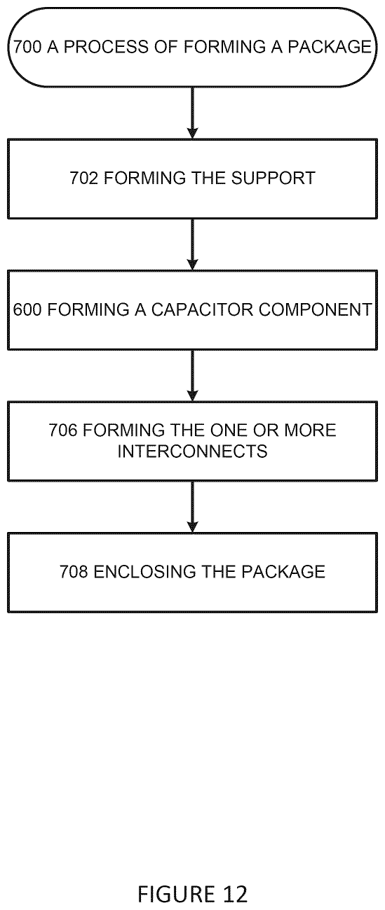

FIG. 12 shows a process of making a package according to the disclosure.

FIG. 12 may include any one or more other features, components, arrangements, and the like as described herein. In particular, FIG. 12 illustrates a process of forming a package 700 that relates to the device 100 as described herein. It should be noted that the aspects of the process of forming a package 700 may be performed in a different order consistent with the aspects described herein. Additionally, it should be noted that portions of the process of forming a package 700 may be performed in a different order consistent with the aspects described herein. Moreover, the process of forming a package 700 may be modified to have more or fewer processes consistent with the various aspects disclosed herein.

Initially, the process of forming a package 700 may include a process of forming the support 702. More specifically, the support component 102 may be constructed, configured, and/or arranged as described herein. In one aspect, the process of forming the support 702 may include forming the support component 102 as a printed circuit board, a MMIC, support, a surface, a package support, a package surface, a package support surface, a flange, a heat sink, a common source heat sink, and/or the like.

The process of forming a package 700 may include the process of forming the capacitor component 600. More specifically, the capacitor component 200 may be constructed, configured, and/or arranged as described herein with reference to FIG. 12 and the associated description thereof. Thereafter, the process of forming the capacitor component 600 may further include attaching the capacitor component 200 to the support component 102. In this regard, the capacitor component 200 may be mounted on the upper surface of the support component 102 by an adhesive, soldering, sintering, eutectic bonding, ultrasonically welding, and/or the like as described herein.

The process of forming a package 700 may include a process of forming the one or more interconnects 706. More specifically, the one or more interconnects 104 may be constructed, configured, and/or arranged as described herein. In one aspect, the process of forming the one or more interconnects 706 may include forming the one or more interconnects 104 by forming one or more wires, leads, vias, edge platings, circuit traces, tracks, and/or the like. In one aspect, the process of forming the one or more interconnects 706 may include connecting the one or more interconnects 706 by an adhesive, soldering, sintering, eutectic bonding, ultrasonic welding, a clip component, and/or the like as described herein.

The process of forming a package 700 may include a process of enclosing the package 708. More specifically, the device 100 may be constructed, configured, and/or arranged as described herein. In one aspect, the process of enclosing the package 708 may include forming an open cavity configuration, an over-mold configuration, or the like.

In one aspect, the process of forming a package 700 may include processing utilizing a surface mount technology (SMT) line. A surface mount technology (SMT) line may utilize numerous processes including solder printing, component placement, solder reflow, and/or the like. Additional processes may include a flux cleaning step to remove all flux residues, wire bonding, dicing, mounting to dicing tape, dicing, either mechanical sawing or laser cutting, or a combination of both, and component testing. Additionally, the capacitor component 200 may be arranged on dicing tape that may then serve as input for the Die Attach equipment.

The following are a number of nonlimiting EXAMPLES of aspects of the disclosure.

One EXAMPLE: a capacitor component includes at least one dielectric layer. The capacitor component in addition includes at least one capacitor top metal. The capacitor component moreover includes at least one capacitor bottom metal. The capacitor component also includes the at least one capacitor top metal, the at least one capacitor bottom metal, and the at least one dielectric layer being configured as a capacitor. The capacitor component further includes at least one metallic structure configured to improve a quality factor of the capacitor and/or reduce a plate resistance of the capacitor. The capacitor component in addition includes where the at least one metallic structure is arranged on the at least one capacitor top metal.

The above-noted EXAMPLE may further include any one or a combination of more than one of the following EXAMPLES: The capacitor component of the above-noted EXAMPLE where the at least one metallic structure is configured as a wire structure, a wire bond structure, a stitched wire bond structure, a looped wire bond structure, a lower height looped wire bond, a zero loop height wire bond, and/or a zero loop height stitched wire bond. The capacitor component of the above-noted EXAMPLE where the at least one metallic structure is arranged directly on the at least one capacitor top metal. The capacitor component of the above-noted EXAMPLE where the at least one metallic structure is connected to the at least one capacitor top metal. The capacitor component of the above-noted EXAMPLE where the at least one metallic structure is directly connected to the at least one capacitor top metal. The capacitor component of the above-noted EXAMPLE where the at least one metallic structure is connected to the at least one capacitor top metal by an adhesive, soldering, sintering, eutectic bonding, thermal compression bonding, and/or ultrasonic bonding/welding. The capacitor component of the above-noted EXAMPLE where the at least one capacitor top metal comprises a capacitor upper surface configured as a connection pad for one or more interconnects. The capacitor component of the above-noted EXAMPLE where the at least one metallic structure is formed of one or more of Aluminum, Copper, Silver, and/or Gold. The capacitor component of the above-noted EXAMPLE where the at least one metallic structure is configured to modify the capacitor to have an improved quality factor. The capacitor component of the above-noted EXAMPLE where the at least one metallic structure is configured to modify the capacitor to have a reduced plate resistance. The capacitor component of the above-noted EXAMPLE where the at least one metallic structure is configured to modify the capacitor to have an improved quality factor and a reduced plate resistance. The capacitor component of the above-noted EXAMPLE where the at least one metallic structure is configured to modify the capacitor to have an improved quality factor through implementation of an additional metallic mass provided by the at least one metallic structure. The capacitor component of the above-noted EXAMPLE where the at least one metallic structure is configured to modify the capacitor to have a reduced plate resistance through implementation of an additional metallic mass provided by the at least one metallic structure. The capacitor component of the above-noted EXAMPLE where the at least one metallic structure reduces an Equivalent Series Resistance (ESR) of the capacitor. The capacitor component of the above-noted EXAMPLE where the at least one metallic structure is configured as a wire structure. The capacitor component of the above-noted EXAMPLE where the at least one metallic structure is configured as a stitched wire bond structure having bond configurations. The capacitor component of the above-noted EXAMPLE where the bond configurations being configured to bond the at least one metallic structure to the at least one capacitor top metal and/or a capacitor upper surface. The capacitor component of the above-noted EXAMPLE where the at least one metallic structure comprises the bond configurations at terminal ends thereof. The capacitor component of the above-noted EXAMPLE where the at least one metallic structure comprises the bond configurations at terminal ends thereof adjacent edges of the capacitor component. The capacitor component of the above-noted EXAMPLE where the at least one metallic structure comprises additional implementations of the bond configurations between the terminal ends thereof. The capacitor component of the above-noted EXAMPLE where the at least one metallic structure is a looped wire bond structure such that portions of the at least one metallic structure extend vertically above the at least one capacitor top metal. The capacitor component of the above-noted EXAMPLE where the capacitor is a MOS (Metal-Oxide-Semiconductor) capacitor. The capacitor component of the above-noted EXAMPLE where the at least one metallic structure is configured to enable an adjustment of a top metal geometry of the capacitor. The capacitor component of the above-noted EXAMPLE where the at least one metallic structure is configured to enable an adjustment of a top metal geometry of the capacitor with respect to a cross sectional area. The capacitor component of the above-noted EXAMPLE where, the at least one metallic structure is configured to enable an adjustment of a top metal geometry of the capacitor with respect to a surface area. The capacitor component of the above-noted EXAMPLE where the at least one metallic structure is configured to enable an adjustment of a top metal geometry of the capacitor with respect to a cross sectional area and a surface area. The device of the above-noted EXAMPLE the device includes one or more interconnects. The device of the above-noted EXAMPLE includes a support component configured to support the capacitor component. The device of the above-noted EXAMPLE where the support component comprises a printed circuit board, a Monolithic Microwave Integrated Circuit (MMIC), and/or a support. The device of the above-noted EXAMPLE where the device 100 is implemented as a RF package, a RF amplifier package, a RF power amplifier package, a RF power transistor package, and/or a RF power amplifier transistor package. The device of the above-noted EXAMPLE includes one or more semiconductor devices.

One EXAMPLE: a capacitor component includes at least one dielectric layer. The capacitor component in addition includes at least one capacitor top metal. The capacitor component moreover includes at least one capacitor bottom metal. The capacitor component also includes the at least one capacitor top metal, the at least one capacitor bottom metal, and the at least one dielectric layer being configured as a capacitor. The capacitor component further includes at least one metallic structure configured to improve a quality factor of the capacitor and/or reduce a plate resistance of the capacitor. The capacitor component in addition includes where the at least one metallic structure comprises at least one wire. The capacitor component moreover includes where the at least one metallic structure is arranged on the at least one capacitor top metal.

The above-noted EXAMPLE may further include any one or a combination of more than one of the following EXAMPLES: The capacitor component of the above-noted EXAMPLE where the at least one metallic structure is configured as a wire structure, a wire bond structure, a stitched wire bond structure, a looped wire bond structure, a lower height looped wire bond, a zero loop height wire bond, and/or a zero loop height stitched wire bond. The capacitor component of the above-noted EXAMPLE where the at least one metallic structure is arranged directly on the at least one capacitor top metal. The capacitor component of the above-noted EXAMPLE where the at least one metallic structure is connected to the at least one capacitor top metal. The capacitor component of the above-noted EXAMPLE where the at least one metallic structure is directly connected to the at least one capacitor top metal. The capacitor component of the above-noted EXAMPLE where the at least one metallic structure is connected to the at least one capacitor top metal by an adhesive, soldering, sintering, eutectic bonding, thermal compression bonding, and/or ultrasonic bonding/welding. The capacitor component of the above-noted EXAMPLE where the at least one capacitor top metal comprises a capacitor upper surface configured as a connection pad for one or more interconnects. The capacitor component of the above-noted EXAMPLE where the at least one metallic structure is formed of one or more of Aluminum, Copper, Silver, and/or Gold. The capacitor component of the above-noted EXAMPLE where the at least one metallic structure is configured to modify the capacitor to have an improved quality factor. The capacitor component of the above-noted EXAMPLE where the at least one metallic structure is configured to modify the capacitor to have a reduced plate resistance. The capacitor component of the above-noted EXAMPLE where the at least one metallic structure is configured to modify the capacitor to have an improved quality factor and a reduced plate resistance. The capacitor component of the above-noted EXAMPLE where the at least one metallic structure is configured to modify the capacitor to have an improved quality factor through implementation of an additional metallic mass provided by the at least one metallic structure. The capacitor component of the above-noted EXAMPLE where the at least one metallic structure is configured to modify the capacitor to have a reduced plate resistance through implementation of an additional metallic mass provided by the at least one metallic structure. The capacitor component of the above-noted EXAMPLE where the at least one metallic structure reduces an Equivalent Series Resistance (ESR) of the capacitor. The capacitor component of the above-noted EXAMPLE where the at least one metallic structure is configured as a wire structure. The capacitor component of the above-noted EXAMPLE where the at least one metallic structure is configured as a stitched wire bond structure having bond configurations. The capacitor component of the above-noted EXAMPLE where the bond configurations being configured to bond the at least one metallic structure to the at least one capacitor top metal and/or a capacitor upper surface. The capacitor component of the above-noted EXAMPLE where the at least one metallic structure comprises the bond configurations at terminal ends thereof. The capacitor component of the above-noted EXAMPLE where the at least one metallic structure comprises the bond configurations at terminal ends thereof adjacent edges of the capacitor component. The capacitor component of the above-noted EXAMPLE where the at least one metallic structure comprises additional implementations of the bond configurations between the terminal ends thereof. The capacitor component of the above-noted EXAMPLE where the at least one metallic structure is a looped wire bond structure such that portions of the at least one metallic structure extend vertically above the at least one capacitor top metal. The capacitor component of the above-noted EXAMPLE where the capacitor is a MOS (Metal-Oxide-Semiconductor) capacitor. The capacitor component of the above-noted EXAMPLE where the at least one metallic structure is configured to enable an adjustment of a top metal geometry of the capacitor. The capacitor component of the above-noted EXAMPLE where the at least one metallic structure is configured to enable an adjustment of a top metal geometry of the capacitor with respect to a cross sectional area. The capacitor component of the above-noted EXAMPLE where, the at least one metallic structure is configured to enable an adjustment of a top metal geometry of the capacitor with respect to a surface area. The capacitor component of the above-noted EXAMPLE where the at least one metallic structure is configured to enable an adjustment of a top metal geometry of the capacitor with respect to a cross sectional area and a surface area. The device of the above-noted EXAMPLE the device includes one or more interconnects. The device of the above-noted EXAMPLE includes a support component configured to support the capacitor component. The device of the above-noted EXAMPLE where the support component comprises a printed circuit board, a Monolithic Microwave Integrated Circuit (MMIC), and/or a support. The device of the above-noted EXAMPLE where the device 100 is implemented as a RF package, a RF amplifier package, a RF power amplifier package, a RF power transistor package, and/or a RF power amplifier transistor package. The device of the above-noted EXAMPLE includes one or more semiconductor devices.

One EXAMPLE: a process includes providing at least one dielectric layer. The process in addition includes providing at least one capacitor top metal. The process moreover includes providing at least one capacitor bottom metal. The process also includes configuring the at least one capacitor top metal, the at least one capacitor bottom metal, and the at least one dielectric layer being as a capacitor. The process further includes configuring at least one metallic structure to improve a quality factor of the capacitor and/or reduce a plate resistance of the capacitor. The process in addition includes where the at least one metallic structure comprises at least one wire. The process moreover includes where the at least one metallic structure is arranged on the at least one capacitor top metal.

The above-noted EXAMPLE may further include any one or a combination of more than one of the following EXAMPLES: The process of the above-noted EXAMPLE where the at least one metallic structure is configured as a wire structure, a wire bond structure, a stitched wire bond structure, a looped wire bond structure, a lower height looped wire bond, a zero loop height wire bond, and/or a zero loop height stitched wire bond. The process of the above-noted EXAMPLE where the at least one metallic structure is arranged directly on the at least one capacitor top metal. The process of the above-noted EXAMPLE where the at least one metallic structure is connected to the at least one capacitor top metal. The process of the above-noted EXAMPLE where the at least one metallic structure is directly connected to the at least one capacitor top metal. The process of the above-noted EXAMPLE where the at least one metallic structure is connected to the at least one capacitor top metal by an adhesive, soldering, sintering, eutectic bonding, thermal compression bonding, and/or ultrasonic bonding/welding. The process of the above-noted EXAMPLE where the at least one capacitor top metal comprises a capacitor upper surface configured as a connection pad for one or more interconnects. The process of the above-noted EXAMPLE where the at least one metallic structure is formed of one or more of Aluminum, Copper, Silver, and/or Gold. The process of the above-noted EXAMPLE where the at least one metallic structure is configured to modify the capacitor to have an improved quality factor. The process of the above-noted EXAMPLE where the at least one metallic structure is configured to modify the capacitor to have a reduced plate resistance. The process of the above-noted EXAMPLE where the at least one metallic structure is configured to modify the capacitor to have an improved quality factor and a reduced plate resistance. The process of the above-noted EXAMPLE where the at least one metallic structure is configured to modify the capacitor to have an improved quality factor through implementation of an additional metallic mass provided by the at least one metallic structure. The process of the above-noted EXAMPLE where the at least one metallic structure is configured to modify the capacitor to have a reduced plate resistance through implementation of an additional metallic mass provided by the at least one metallic structure. The process of the above-noted EXAMPLE where the at least one metallic structure reduces an Equivalent Series Resistance (ESR) of the capacitor. The process of the above-noted EXAMPLE where the at least one metallic structure is configured as a wire structure. The process of the above-noted EXAMPLE where the at least one metallic structure is configured as a stitched wire bond structure having bond configurations. The process of the above-noted EXAMPLE where the bond configurations being configured to bond the at least one metallic structure to the at least one capacitor top metal and/or a capacitor upper surface. The process of the above-noted EXAMPLE where the at least one metallic structure comprises the bond configurations at terminal ends thereof. The process of the above-noted EXAMPLE where the at least one metallic structure comprises the bond configurations at terminal ends thereof adjacent edges of the capacitor component. The process of the above-noted EXAMPLE where the at least one metallic structure comprises additional implementations of the bond configurations between the terminal ends thereof. The process of the above-noted EXAMPLE where the at least one metallic structure is a looped wire bond structure such that portions of the at least one metallic structure extend vertically above the at least one capacitor top metal. The process of the above-noted EXAMPLE where the capacitor is a MOS (Metal-Oxide-Semiconductor) capacitor. The process of the above-noted EXAMPLE where the at least one metallic structure is configured to enable an adjustment of a top metal geometry of the capacitor. The process of the above-noted EXAMPLE where the at least one metallic structure is configured to enable an adjustment of a top metal geometry of the capacitor with respect to a cross sectional area. The process of the above-noted EXAMPLE where, the at least one metallic structure is configured to enable an adjustment of a top metal geometry of the capacitor with respect to a surface area. The process of the above-noted EXAMPLE where the at least one metallic structure is configured to enable an adjustment of a top metal geometry of the capacitor with respect to a cross sectional area and a surface area.

One EXAMPLE: a process includes providing at least one dielectric layer. The process in addition includes providing at least one capacitor top metal. The process moreover includes providing at least one capacitor bottom metal. The process also includes configuring the at least one capacitor top metal, the at least one capacitor bottom metal, and the at least one dielectric layer being as a capacitor. The process further includes configuring at least one metallic structure to improve a quality factor of the capacitor and/or reduce a plate resistance of the capacitor. The process in addition includes where the at least one metallic structure is arranged on the at least one capacitor top metal.

The above-noted EXAMPLE may further include any one or a combination of more than one of the following EXAMPLES: The process of the above-noted EXAMPLE where the at least one metallic structure is configured as a wire structure, a wire bond structure, a stitched wire bond structure, a looped wire bond structure, a lower height looped wire bond, a zero loop height wire bond, and/or a zero loop height stitched wire bond. The process of the above-noted EXAMPLE where the at least one metallic structure is arranged directly on the at least one capacitor top metal. The process of the above-noted EXAMPLE where the at least one metallic structure is connected to the at least one capacitor top metal. The process of the above-noted EXAMPLE where the at least one metallic structure is directly connected to the at least one capacitor top metal. The process of the above-noted EXAMPLE where the at least one metallic structure is connected to the at least one capacitor top metal by an adhesive, soldering, sintering, eutectic bonding, thermal compression bonding, and/or ultrasonic bonding/welding. The process of the above-noted EXAMPLE where the at least one capacitor top metal comprises a capacitor upper surface configured as a connection pad for one or more interconnects. The process of the above-noted EXAMPLE where the at least one metallic structure is formed of one or more of Aluminum, Copper, Silver, and/or Gold. The process of the above-noted EXAMPLE where the at least one metallic structure is configured to modify the capacitor to have an improved quality factor. The process of the above-noted EXAMPLE where the at least one metallic structure is configured to modify the capacitor to have a reduced plate resistance. The process of the above-noted EXAMPLE where the at least one metallic structure is configured to modify the capacitor to have an improved quality factor and a reduced plate resistance. The process of the above-noted EXAMPLE where the at least one metallic structure is configured to modify the capacitor to have an improved quality factor through implementation of an additional metallic mass provided by the at least one metallic structure. The process of the above-noted EXAMPLE where the at least one metallic structure is configured to modify the capacitor to have a reduced plate resistance through implementation of an additional metallic mass provided by the at least one metallic structure. The process of the above-noted EXAMPLE where the at least one metallic structure reduces an Equivalent Series Resistance (ESR) of the capacitor. The process of the above-noted EXAMPLE where the at least one metallic structure is configured as a wire structure. The process of the above-noted EXAMPLE where the at least one metallic structure is configured as a stitched wire bond structure having bond configurations. The process of the above-noted EXAMPLE where the bond configurations being configured to bond the at least one metallic structure to the at least one capacitor top metal and/or a capacitor upper surface. The process of the above-noted EXAMPLE where the at least one metallic structure comprises the bond configurations at terminal ends thereof. The process of the above-noted EXAMPLE where the at least one metallic structure comprises the bond configurations at terminal ends thereof adjacent edges of the capacitor component. The process of the above-noted EXAMPLE where the at least one metallic structure comprises additional implementations of the bond configurations between the terminal ends thereof. The process of the above-noted EXAMPLE where the at least one metallic structure is a looped wire bond structure such that portions of the at least one metallic structure extend vertically above the at least one capacitor top metal. The process of the above-noted EXAMPLE where the capacitor is a MOS (Metal-Oxide-Semiconductor) capacitor. The process of the above-noted EXAMPLE where the at least one metallic structure is configured to enable an adjustment of a top metal geometry of the capacitor. The process of the above-noted EXAMPLE where the at least one metallic structure is configured to enable an adjustment of a top metal geometry of the capacitor with respect to a cross sectional area. The process of the above-noted EXAMPLE where, the at least one metallic structure is configured to enable an adjustment of a top metal geometry of the capacitor with respect to a surface area. The process of the above-noted EXAMPLE where the at least one metallic structure is configured to enable an adjustment of a top metal geometry of the capacitor with respect to a cross sectional area and a surface area.

Accordingly, the disclosure has set forth a capacitor configured to modify a quality factor Q. Additionally or alternatively, the disclosure has set forth a capacitor configured to reduce a plate resistance.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a conductive mass of material by heat and/or pressure. The sintering process may operate without melting the material to the point of liquefaction. The sintering process may include sintering of metallic nano or hybrid powders in pastes or epoxies. The sintering process may include sintering in a vacuum. The sintering process may include sintering with the use of a protective gas.

The eutectic bonding of the disclosure may utilize a eutectic soldering process that may form a eutectic system. The eutectic system may be used between surfaces to be connected. The eutectic bonding may utilize metals that may be alloys and/or intermetallics that transition from solid to liquid state, or from liquid to solid state, at a specific composition and temperature. The eutectic alloys may be deposited by sputtering, evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure.

1. A capacitor component comprising:
at least one dielectric layer;
at least one capacitor top metal;
at least one capacitor bottom metal;
the at least one capacitor top metal, the at least one capacitor bottom metal, and the at least one dielectric layer being configured as a capacitor; and
at least one metallic structure configured to improve a quality factor of the capacitor and/or reduce a plate resistance of the capacitor,
wherein the at least one metallic structure is arranged on the at least one capacitor top metal.

2. The capacitor component according to claim 1 wherein the at least one metallic structure is configured as a wire structure, a wire bond structure, a stitched wire bond structure, a looped wire bond structure, a lower height looped wire bond, a zero loop height wire bond, and/or a zero loop height stitched wire bond.

3. (canceled)

4. The capacitor component according to claim 1 wherein the at least one metallic structure is connected to the at least one capacitor top metal.

5. (canceled)

6. (canceled)

7. The capacitor component according to claim 1 wherein the at least one capacitor top metal comprises a capacitor upper surface configured as a connection pad for one or more interconnects.

8. (canceled)

9. The capacitor component according to claim 1 wherein the at least one metallic structure is configured to modify the capacitor to have an improved quality factor.

10. The capacitor component according to claim 1 wherein the at least one metallic structure is configured to modify the capacitor to have a reduced plate resistance.

11. The capacitor component according to claim 1 wherein the at least one metallic structure is configured to modify the capacitor to have an improved quality factor and a reduced plate resistance.

12. The capacitor component according to claim 1 wherein the at least one metallic structure is configured to modify the capacitor to have an improved quality factor through implementation of an additional metallic mass provided by the at least one metallic structure.

13. The capacitor component according to claim 1 wherein the at least one metallic structure is configured to modify the capacitor to have a reduced plate resistance through implementation of an additional metallic mass provided by the at least one metallic structure.

14. The capacitor component according to claim 1 wherein the at least one metallic structure reduces an Equivalent Series Resistance (ESR) of the capacitor.

15. The capacitor component according to claim 1 wherein the at least one metallic structure is configured as a wire structure.

16. The capacitor component according to claim 1 wherein the at least one metallic structure is configured as a stitched wire bond structure having bond configurations.

17. The capacitor component according to claim 16 wherein the bond configurations being configured to bond the at least one metallic structure to the at least one capacitor top metal and/or a capacitor upper surface.

18. The capacitor component according to claim 16 wherein the at least one metallic structure comprises the bond configurations at terminal ends thereof.

19. The capacitor component according to claim 16 wherein the at least one metallic structure comprises the bond configurations at terminal ends thereof adjacent edges of the capacitor component.

20. The capacitor component according to claim 19 wherein the at least one metallic structure comprises additional implementations of the bond configurations between the terminal ends thereof.

21. The capacitor component according to claim 1 wherein the at least one metallic structure is a looped wire bond structure such that portions of the at least one metallic structure extend vertically above the at least one capacitor top metal.

22. The capacitor component according to claim 1 wherein the capacitor is a MOS (Metal-Oxide-Semiconductor) capacitor.

23. The capacitor component according to claim 1 wherein the at least one metallic structure is configured to enable an adjustment of a top metal geometry of the capacitor.

24.-26. (canceled)

27. A device comprising the capacitor component according to claim 1, the device further comprising one or more interconnects.

28. (canceled)

29. (canceled)

30. The device according to claim 27 wherein the device 100 is implemented as a RF package, a RF amplifier package, a RF power amplifier package, a RF power transistor package, and/or a RF power amplifier transistor package.

31. (canceled)

32. A capacitor component comprising:
at least one dielectric layer;
at least one capacitor top metal;
at least one capacitor bottom metal;
the at least one capacitor top metal, the at least one capacitor bottom metal, and the at least one dielectric layer being configured as a capacitor; and
at least one metallic structure configured to improve a quality factor of the capacitor and/or reduce a plate resistance of the capacitor,
wherein the at least one metallic structure comprises at least one wire; and
wherein the at least one metallic structure is arranged on the at least one capacitor top metal.

33.-62. (canceled)

63. A process of implementing a capacitor component comprising:
providing at least one dielectric layer;
providing at least one capacitor top metal;
providing at least one capacitor bottom metal;
configuring the at least one capacitor top metal, the at least one capacitor bottom metal, and the at least one dielectric layer being as a capacitor; and
configuring at least one metallic structure to improve a quality factor of the capacitor and/or reduce a plate resistance of the capacitor,
wherein the at least one metallic structure comprises at least one wire; and
wherein the at least one metallic structure is arranged on the at least one capacitor top metal.

64.-114. (canceled)
